(19) United States
(12) Patent Application Publication
(10) Pub. No.: US 2017/0331511 A1
(43) Pub. Date: Nov. 16, 2017

(54) TRANSCEIVER SWITCH OF RADIO FREQUENCY TRANSCEIVER

(71) Applicant: FCI INC., Gyeonggi-do (KR)

(72) Inventors: Heeyoung YOO, Gyeonggi-do (KR); Jecheol MOON, Gyeonggi-do (KR); Myungwoon HWANG, Gyeonggi-do (KR)

(21) Appl. No.: 15/594,957

(22) Filed: May 15, 2017

(30) Foreign Application Priority Data
May 16, 2016 (KR) 10-2016-0059470

(51) Int. Cl. H04B 1/48; H01L 27/02; H02H 9/04; H03K 17/687

(52) U.S. Cl. CPC H04B 1/48; H03K 17/687; H01L 27/0255; H02H 9/046

(57) ABSTRACT

A transceiver switch of a radio frequency transceiver is provided with a first diode and a second diode included in an electrostatic discharge circuit, which are connected in parallel along different directions to ground a positive (+) current or a negative (−) current generated from electrostatic charges. Another transceiver switch of a radio frequency transceiver is also provided with a resistor connected between a node connecting to an electrostatic discharge circuit and a ground terminal, to make the voltage of the node connecting to the electrostatic discharge circuit become a fixed DC potential connecting to the ground terminal.

### CROSS REFERENCE TO RELATED APPLICATION

This application claims the benefit of priority of a Korean Patent Application No. 10-2016-0059470 submitted to Korean Intellectual Property Office on May 16, 2016, entitled “TRANSCEIVER SWITCH OF RADIO FREQUENCY TRANSCEIVER,” the contents of which are incorporated herein by reference in their entirety.

### BACKGROUND

### 1. Field of the Disclosure

The present disclosure relates to a transceiver switch of a radio frequency (RF) transceiver.

### 2. Description of Related Art

The content in this section is merely provided for illustration of a background of embodiments of the present disclosure, and should not be treated as prior arts.

Electrostatic discharge (ESD) is a movement of electronic charges caused by a potential difference. An electronic pulse of high voltage and high current generated from the electrostatic discharge may damage an electronic apparatus or cause mis-operations of the electronic apparatus. The electrostatic discharge becomes sensitive because of micronization of manufacturing processes, size reduction of transistors, and spatial restriction of chips. Therefore, an electrostatic discharge circuit or an electrostatic discharge protection circuit is needed in the electronic apparatus.

A transceiver switch of a radio frequency transceiver needs the electrostatic discharge circuit, but approaches to carry out the electrostatic discharge circuit are limited indeed. For example, the electrostatic discharge circuit cannot be connected to an input output pin of the switch. The reason for this is that diodes will be turned on if the output of a transmitter is too high.

In carrying out the electrostatic discharge circuit in the transceiver switch of the radio frequency transceiver, some approaches involve a use of a clamp circuit and an additional supply voltage. For example, the clamp circuit provides the supply voltage ranged from −1V (volt) to +1V. In these approaches, a power supply (e.g., a clamp cell) is needed in the clamp circuit.

In carrying out the electrostatic discharge circuit in the transceiver switch of the radio frequency transceiver, other approaches involve a use of a plurality of diodes connected in series to the ground. In these approaches, a turn-one voltage of the diodes is increased with the increase of the number of the diodes.

Actually, none of existing transceiver switches can solve above problems so far.

### SUMMARY

### Problems to be Solved

Inventor(s) of the application notices that connection of an electrostatic discharge circuit is limited in a transceiver switch of a RF transceiver, and as such, tries to minimize the area occupied in a chip by the electrostatic discharge circuit in an aspect and to reduce a voltage starting to activating the electrostatic discharge circuit in another aspect.

A primary objective of the present disclosure is to ground a positive (+) current or a negative (−) current generated from electrostatic charges, by deploying a first diode and a second diode connected in parallel along different directions in the electrostatic discharge circuit.

Another objective of the present disclosure is to make the voltage of a node connecting to the electrostatic discharge circuit become a fixed DC potential connecting to a ground terminal, by deploying a resistor connected between the node connecting to the electrostatic discharge circuit and the ground terminal.

### Means for Solving the Problems

In accordance with an embodiment of the present disclosure, a transceiver switch of a RF transceiver is provided. The transceiver switch includes a transmitting circuit, including a first switch connected between an output port of a power amplifier of the RF transceiver and an input output port of the RF transceiver; and a receiving circuit, including a second switch connected between an input port of a low noise amplifier of the RF transceiver and a ground terminal. The input port of the low noise amplifier of the RF transceiver is coupled to the input output port of the RF transceiver via inductive coupling. The receiving circuit further comprises an electrostatic discharge circuit, which releases a surge voltage applied to the input output port of the RF transceiver if a magnitude of the surge voltage is greater than or equal to that of a discharge starting voltage of the electrostatic discharge circuit. Further, the electrostatic discharge circuit comprising an electrostatic discharge node connecting to the second switch.

In accordance with another embodiment of the present disclosure, a RF transceiver is provided. The RF transceiver includes a transceiver switch, a wireless transmitter, and a wireless receiver. The transceiver switch includes a transmitting circuit, including a first switch connected between an output port of a power amplifier of the RF transceiver and an input output port of the RF transceiver; and a receiving circuit, including a second switch connected between an input port of a low noise amplifier of the RF transceiver and a ground terminal. The input port of the low noise amplifier of the RF transceiver is coupled to the input output port of the RF transceiver via inductive coupling. The receiving circuit further comprises an electrostatic discharge circuit, which releases a surge voltage applied to the input output port of the RF transceiver if a magnitude of the surge voltage is greater than or equal to that of a discharge starting voltage of the electrostatic discharge circuit. Further, the electrostatic discharge circuit comprising an electrostatic discharge node connecting to the second switch.

### Technical Effects

As described above, the embodiments of the present disclosure have the following beneficial effects. The first diode and the second diode configured to release electrostatic charges are connected in parallel along different directions, and are connected to the resistor in the electrostatic discharge circuit. As such, the diodes are quickly turned on to pull the magnitude of the peak voltage of the node connecting to the electrostatic discharge circuit down to the magnitude of the predetermined threshold voltage (e.g., a turn-on voltage of the diodes). In other words, this prevents transistors from being damaged by a surge voltage (i) greater than the magnitude of the predetermined threshold voltage and less than the magnitude of the sum of the predetermined threshold voltage and a supply voltage; or (ii) greater than the magnitude of the predetermined threshold voltage and less than the magnitude of the sum of the predetermined threshold voltage and an unknown voltage.

The effects described in the present disclosure and other potential effects are achieved by technical features of the present disclosure. The effects that are not specifically described herein should be treated as the effects described in the present disclosure.

### BRIEF DESCRIPTION OF THE DRAWINGS

FIG. 1 is a schematic diagram showing a RF transceiver in accordance with an embodiment of the present disclosure.

FIG. 2 is a block diagram showing a transceiver switch of a RF transceiver in accordance with an embodiment of the present disclosure.

FIG. 3 is a diagram exemplarily showing a transceiver switch of a RF transceiver in the absence of an electrostatic discharge circuit in accordance with an embodiment of the present disclosure.

FIGS. 4 and 5 are schematic diagrams showing a transceiver switch of a RF transceiver operated in a transmitting mode in the absence of an electrostatic discharge circuit in accordance with an embodiment of the present disclosure.

FIGS. 6 and 7 are schematic diagrams showing a transceiver switch of a RF transceiver operated in a receiving mode in the absence of an electrostatic discharge circuit in accordance with an embodiment of the present disclosure.

FIGS. 8 and 9 are diagrams exemplarily showing a transceiver switch of a RF transceiver in accordance with an embodiment of the present disclosure.

### DETAILED DESCRIPTION OF THE PREFERRED EMBODIMENTS

Related common knowledge is well understood by a person of ordinary skill in the art, and therefore is not detailed in illustrating the present disclosure in order avoid confusion about the objectives of the present disclosure. A part of embodiments of the present disclosure are illustrated in detail below with reference to appending exemplary drawings.

The embodiments described in the present disclosure are applicable to a wireless communication system. The wireless communication system may include at least a communication device. The communication device is wirelessly connected to other communication device(s) and data communication is carried out therebetween in real time or non-real time. In other words, the communication devices constitute a communication network. Further, the communication device may be referred to a mobile station (MS), a mobile terminal, a user terminal (UT), a subscriber station (SS), a wireless device, a personal digital assistant (PDA), a wireless modem, a handheld device, and so on.

The wireless communication system may include at least a base station (BS). The communication device is wirelessly connected to the base station. The base station is a station communicating with the communication device, and may be implemented by eNB (evolved-Node B), BTS (Base Transceiver System), or an access point.

Various protocols are appropriate to the wireless connection. Exemplary protocols are IEEE (Institute of Electrical and Electronics Engineers) 802.11, WiFi (Wireless Fidelity), Bluetooth, ZigBee, WiMAX (Worldwide Interoperability for Microwave Access), WiBro (Wireless Broadband), LTE (Long Term Evolution), but the present disclosure is not limited thereto.

The wireless communication system may adopt various multiple access transmission technologies, for example, CDMA (Code Division Multiple Access), FDMA (Frequency Division Multiple Access), TDMA (Time Division Multiple Access), OFDMA (Orthogonal Frequency Division Multiple Access), CSMA (Carrier Sense Multiple Access), but the present disclosure is not limited thereto. The wireless communication system may adopt various duplexing technologies in bidirectional communication, for example, FDD (Frequency Division Duplexing) and TDD (Time Division Duplexing), but the present disclosure is not limited thereto.

The wireless communication system may adopt multi-antenna technology such as MIMO (Multiple Input Multiple Output) systems, but the present disclosure is not limited thereto.

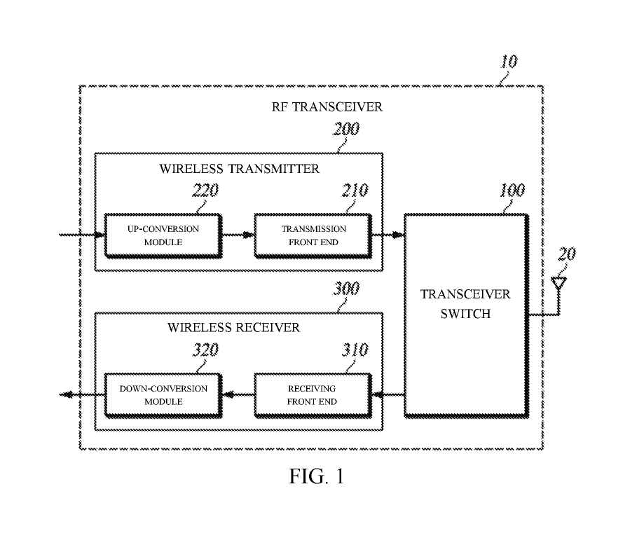

FIG. 1 is a schematic diagram showing a RF (radio frequency) transceiver in accordance with an embodiment of the present disclosure. As shown in FIG. 1, the RF transceiver 10 includes a transceiver switch 100, a wireless transmitter 200, and a wireless receiver 300. The RF transceiver 10 may be represented exemplarily by a plurality of elements, part of which are omitted in FIG. 1, or other additional elements may be further included in FIG. 1.

The RF transceiver 10 is a device connecting to an antenna 20 to transmit and receive data. The wireless transmitter 200 and the wireless receiver 300 share a same antenna 20. The transceiver switch 100 is utilized in the RF transceiver 10 to selectively operate the wireless transmitter 200 and the wireless receiver 300. A single one antenna 20 is shown in FIG. 1, but a plurality of antennas may be implemented as well.

The wireless transmitter 200 converts a baseband frequency signal into a radio frequency (RF) signal and transmits the same to the antenna 20. Also, the wireless transmitter 200 can convert the baseband frequency into an intermediate frequency (IF) signal, and then convert the IF signal into the RF signal. High frequency selectivity is carried out by the wireless transmitter 200 using the IF signal.

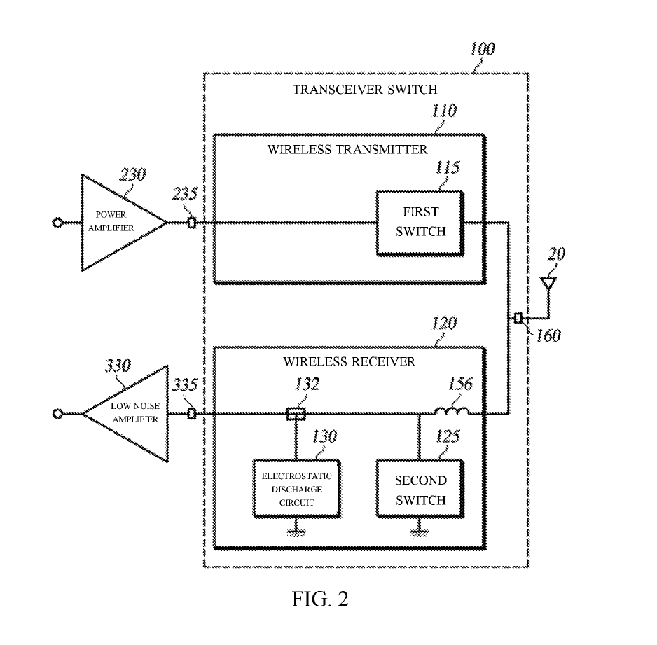

The wireless transmitter 200 includes an up-conversion module 220 and a transmission front end 210. The up-conversion module 220 includes at least one of a digital to analog converter (DAC), a frequency filter, and a mixer. The DAC converts a digital baseband frequency signal into an analogy baseband frequency signal, or converts a digital IF signal into an analogy IF signal. The frequency filter may be a band pass filter (BPF), but the present disclosure is not limited thereto. The mixer mixes the baseband frequency signal (or the IF signal) and a signal from a local oscillator to increase the frequency and convert the mixed signal into the RF signal. The transmission front end 210 includes at least one of a power amplifier 230 (see FIG. 2) and a frequency filter. The power amplifier 230 amplifies the power of the RF signal.

The wireless receiver 300 receives a RF signal from the antenna 20 and converts the RF signal into a baseband frequency signal. The wireless receiver 300 may convert the RF signal into an IF signal, and then convert the IF signal into the baseband signal. High frequency selectivity is carried out by the wireless receiver 300 using the IF signal.

The wireless receiver 300 includes a receiving front end 310 and a down-conversion module 320. The receiving front end 310 includes at least one of a low noise amplifier 330 (see FIG. 2) and a frequency filter. The frequency filter may be a band pass filter, but the present disclosure is not limited thereto. The low noise amplifier 330 amplifies the RF signal and minimizes the noise. The down-conversion module 320 includes at least one of a mixer, a frequency filter, and an analog to digital converter (ADC). The mixer mixes the RF signal and a signal from a local oscillator to decrease the frequency and convert the mixed signal into baseband frequency signal or IF signal. The ADC converts an analogy baseband frequency signal into a digital baseband frequency signal, or converts an analogy IF signal into a digital IF signal.

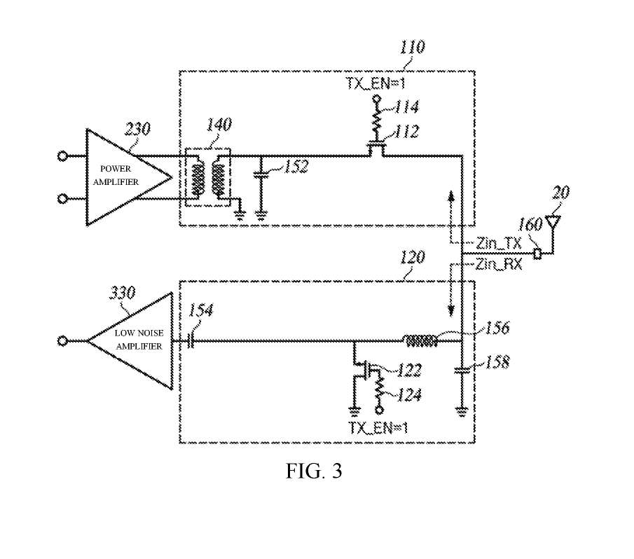

FIG. 2 is a block diagram showing a transceiver switch of a RF transceiver in accordance with an embodiment of the present disclosure. FIG. 3 is a diagram exemplarily showing a transceiver switch of a RF transceiver in the absence of an electrostatic discharge circuit in accordance with an embodiment of the present disclosure. As shown in FIG. 2, the transceiver switch 100 includes a transmitting circuit 110 and a receiving circuit 120. The transceiver switch 100 may be represented exemplarily by a plurality of elements, part of which are omitted in FIG. 2, or other additional elements may be further included in FIG. 2.

Referring to FIG. 2, the transmitting circuit 110 includes a first switch 115 connected between an output port 235 of the power amplifier 230 and an input output port 160 of the RF transceiver. The input output port 160 is connected to the antenna 20.

The receiving circuit 120 includes a second switch 125 connected between an input port 330 of the low noise amplifier 330 and ground. The input port 335 of the low noise amplifier 330 of the RF transceiver is coupled to the input output port 160 of the RF transceiver via inductive coupling 156. The receiving circuit 120 includes an electrostatic discharge circuit 130.

If the magnitude of a surge voltage applied to the input output port 160 of the RF transceiver is greater than or equal to the magnitude of a discharge starting voltage, the electrostatic discharge circuit 130 releases the surge voltage. For example, the surge voltage is 3V and the discharge starting voltage is 2V. Alternatively, the surge voltage is −2V and the discharge starting voltage is −1V. These are only examples. The present disclosure is not limited to these examples. The reason to compare the magnitude of a voltage is that the voltage has a positive polarity (+) and a negative polarity (−). The electrostatic discharge circuit 130 includes an ESD node 132 connecting to the second switch 125.

The electrostatic discharge circuit 130 may include a first diode and a second diode. The first diode is connected between the ESD node 132 and ground along a first direction. The second diode is connected between the ESD node 132 and ground along a second direction. The first direction and the second direction are opposite to each other. The magnitude of the discharge starting voltage is an absolute value of the sum of i) a predetermined threshold voltage and ii) the voltage of the ESD node 132. The voltage of the ESD node 132 may be a DC (direct current) voltage connecting to the ground. The predetermined threshold voltage is a turn-on voltage of the diode.

The first diode and the second diode configured to release electrostatic charges are connected in parallel in the electrostatic discharge circuit 130 along different directions, and are connected to a resistor of the electrostatic discharge circuit 130. This causes an effect that these diodes are quickly turned on to pull the magnitude of a peak voltage of the node connecting to the electrostatic discharge circuit 130 down to the magnitude of the predetermined threshold voltage. In other words, this prevents transistors from being damaged by a surge voltage (i) greater than the magnitude of the predetermined threshold voltage and less than the magnitude of the sum of the predetermined threshold voltage and a supply voltage; or (ii) greater than the magnitude of the predetermined threshold voltage and less than the magnitude of the sum of the predetermined threshold voltage and an unknown voltage.

Referring to FIG. 3, the first switch 115 can be implemented by a transistor 112. The transmitting circuit 110 may further include a BALUN (BALanced-to-UNbalanced) transformer. The BALUN transformer is connected to the output port 235 of the power amplifier 230 of the RF transceiver to convert a differential output signal to a single ended output signal. A capacitor 152 may be connected between the first switch 115 and ground. A resistor 114 may be connected between the transistor 112 and ground.

The second switch 125 can be implemented by a transistor 122. The second switch 125 may be coupled to the input port 335 of the low noise amplifier 330 of the RF transceiver via capacitive coupling. That is, a capacitor 154 may be connected between the second switch 125 and the input port 335 of the low noise amplifier 330. The second switch 125 may be coupled to the input output port 160 of the RF transceiver via inductive coupling. That is, an inductor 156 may be connected between the second switch 125 and the input output port 160. A capacitor 158 may be connected between the transmitting circuit 110 and ground. A resistor 124 may be connected between the transistor 122 and ground.

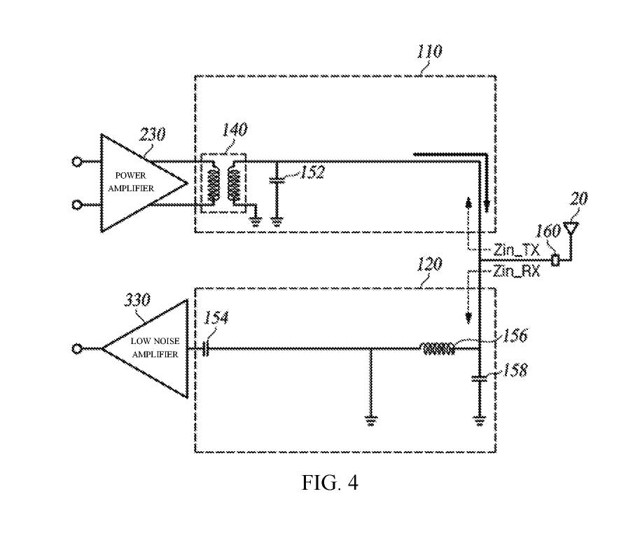

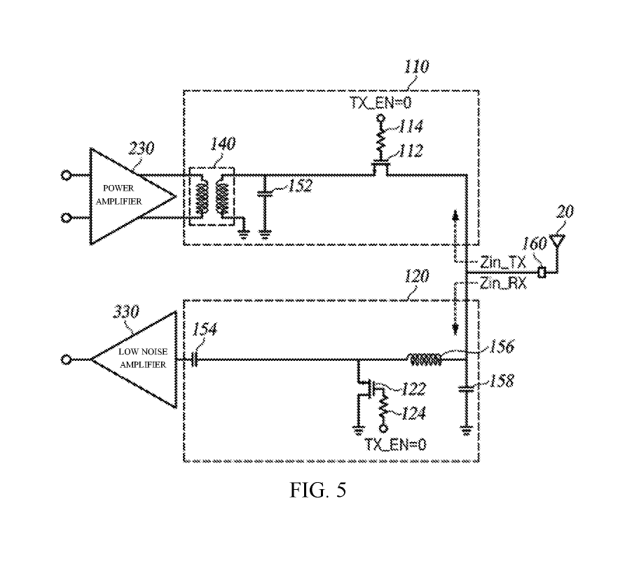

Operations of the transceiver switch 100 in a transmitting mode are illustrated below. FIGS. 4 and 5 are schematic diagrams showing a transceiver switch of a RF transceiver operated in a transmitting mode in the absence of an electrostatic discharge circuit in accordance with an embodiment of the present disclosure.

If the RF transceiver 10 is operated in the transmitting mode, the first switch 115 (e.g., the transistor 112) is turned on in response to a transmitting signal in a transmitting state, to connect the output port 235 of the power amplifier 230 of the RF transceiver to the input output port 160 of the RF transceiver. The second switch 125 (e.g., the transistor 122) is turned on in response to the transmitting signal in the transmitting state, to ground the input port 335 of the low noise amplifier 330 of the RF transceiver.

Referring to FIG. 4, the first switch 115 (e.g., the transistor 112) and the second switch 125 (e.g., the transistor 122) are turned on when receiving the transmitting signal (TX_EN=1) in the transmitting state. Thus, the impedance (Zin_TX) of the transmitting circuit 110 is a low value. For example, the impedance (Zin_TX) may match with 50 ohms. In contrary, the impedance (Zin_RX) of the receiving circuit 120 is a high value. Under the operating frequency of the RF transceiver 10, the inductor 156 resonates with the capacitor 158 to cause a high impedance for Zin_RX. In the transmitting mode, the first switch 115 (e.g., the transistor 112), the second switch 125 (e.g., the transistor 122), Zin_TX, and Zin_RX may be operated as that shown in FIG. 5. Therefore, most of signals are flowing toward the input output port 160, instead of the receiving circuit 120.

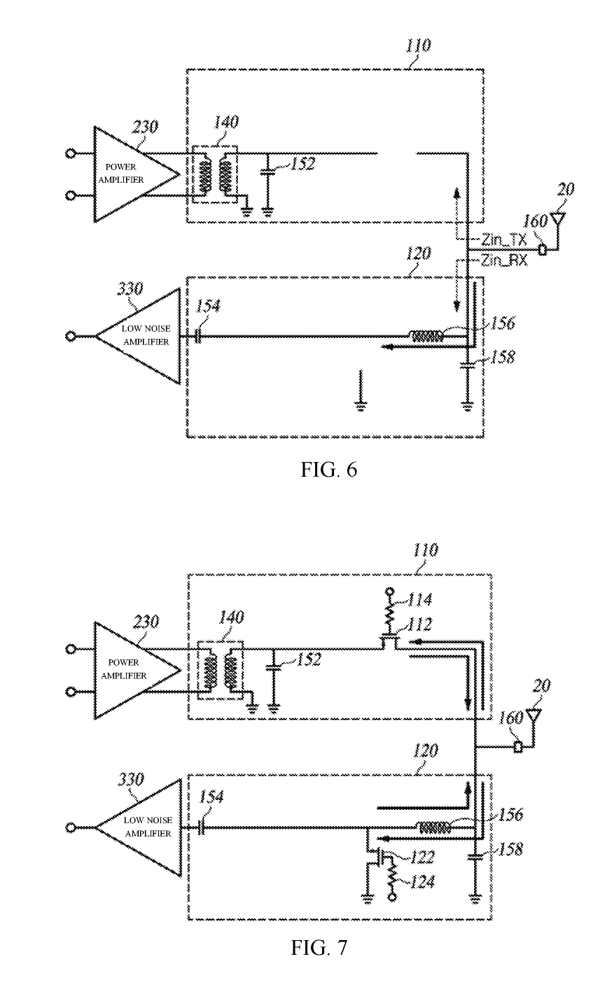

Operations of the transceiver switch 100 in a receiving mode are illustrated below. FIGS. 6 and 7 are schematic diagrams showing a transceiver switch of a RF transceiver operated in a receiving mode in the absence of an electrostatic discharge circuit in accordance with an embodiment of the present disclosure.

If the RF transceiver 10 is operated in the receiving mode, the first switch 115 (e.g., the transistor 112) is turned off in response to a receiving signal in a receiving state, to disconnect the output port 235 of the power amplifier 230 of the RF transceiver from the input output port 160 of the RF transceiver. The second switch 125 (e.g., the transistor 122) is turned off in response to the receiving signal in the receiving state, so as not to ground the input port 335 of the low noise amplifier 330 of the RF transceiver.

Referring to FIG. 6, the first switch 115 (e.g., the transistor 112) and the second switch 125 (e.g., the transistor 122) are turned off when receiving the receiving signal (TX_EN=0) in the receiving state. Thus, the impedance (Zin_TX) of the transmitting circuit 110 is an infinite value. In contrary, the impedance (Zin_RX) of the receiving circuit 120 is a low value. For example, the inductor 156 resonates with the capacitor 158 to match Zin_RX with 50 ohms. In the receiving mode, the first switch 115 (e.g., the transistor 112), the second switch 125 (e.g., the transistor 122), Zin_TX, and Zin_RX may be operated as that shown in FIG. 7. Therefore, the signals inputted from the input output port 160 are transmitted to the receiving circuit 120.

Referring to FIGS. 3, 8, and 9, operations of a transceiver switch of a RF transceiver of an exemplary embodiment are illustrated below.

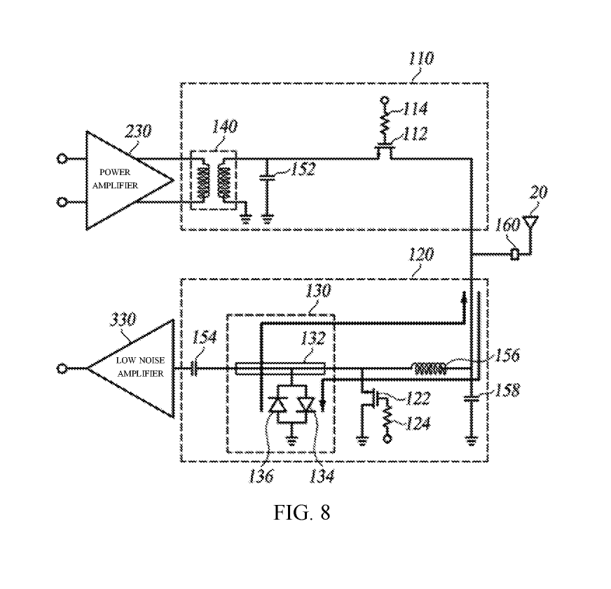

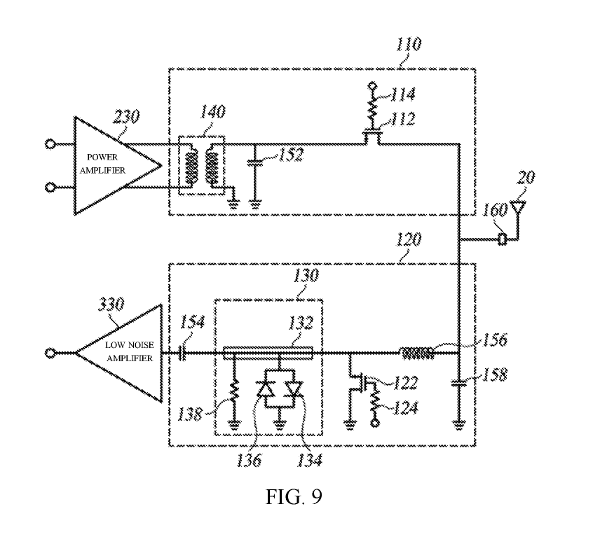

Referring back to FIG. 3, if the electrostatic discharge circuit 130 is not included in the transceiver switch 100, a surge current flowing from the antenna 20 may damage the transmitting circuit 110 or the receiving circuit 120. In order to solve such a problem, inventor(s) of the application proposes to connect a first diode and a second diode in parallel along different directions to make the surge current flow to the ground. Also, a resistor is connected between ground and a node connecting to the electrostatic discharge circuit to make the potential of the node connecting to the electrostatic discharge circuit become a constant by DC bias. FIGS. 8 and 9 are diagrams exemplarily showing a transceiver switch of a RF transceiver in accordance with an embodiment of the present disclosure.

As shown in FIG. 8, the electrostatic discharge circuit 130 includes a first diode 134 and a second diode 136. The first diode 134 and the second diode 136 are connected between an ESD node 132 and ground. The first diode 134 and the second diode 136 are connected in parallel. The first diode 134 may be connected between the ESD node 132 and ground along a first direction. The second diode 136 may be connected between the ESD node 132 and ground along a second direction. The first direction and the second direction are opposite directions.

Referring to FIG. 9, the electrostatic discharge circuit 130 includes a resistor 138. The resistor 138 is connected between the ESD node 132 and ground. If the magnitude of a surge voltage applied to the input output port 160 of the RF transceiver is greater than or equal to the magnitude of a discharge starting voltage, the electrostatic discharge circuit 130 releases the surge voltage. The magnitude of the discharge starting voltage is an absolute value of the sum of a predetermined threshold voltage and the voltage of the ESD node 132. The predetermined threshold voltage is a turn-on voltage of the diodes 134 and 136. The voltage of the ESD node 132 is may be a DC voltage connecting to the ground. The electrostatic discharge circuit 130 may be coupled to the input port 335 of the low noise amplifier 330 of the RF transceiver via capacitive coupling.

The first diode 134 and the second diode 136 are connected in parallel in the electrostatic discharge circuit 130 along different directions, and are connected to the resistor 138 of the electrostatic discharge circuit 130. In such a way, a supply power (i.e., a clamp unit) of a clamp circuit is not required. Since an additional power supply wire is not needed, the layout area is reduced as well as the number of pads and the parasitic capacitance.

The first diode 134 and the second diode 136 are connected in parallel in the electrostatic discharge circuit 130 along different directions, and are connected to the ground via the resistor 138 of the electrostatic discharge circuit 130. In such a way, the surge current may flow to the ground as long as the surge voltage is greater than or equal to the predetermined threshold voltage. That is, the diodes 134 and 136 are turned on more quickly.

The first diode 134 and the second diode 136 are connected in parallel in the electrostatic discharge circuit 130 along different directions, and are connected to the ground via the resistor 138 of the electrostatic discharge circuit 130. In such a way, the magnitude of a peak voltage of the ESD node 132 is reduced. Since the magnitude of the peak voltage of the ESD node 132 is small, transistors can be protected without being affected by a surge voltage greater than the turn-on voltage of the diodes 134 and 136. The reason is that the magnitude of the peak voltage of the ESD node 132 may become large if the resistor 138 is not disposed, and thus the voltage of the ESD node 132 may be turned to a voltage of supply power or an unknown voltage.

In a situation that the electrostatic discharge circuit 130 applies a supply voltage under the receiving mode to the RF transceiver 10 to shut down the RF transceiver 10, the discharge starting voltage changes to the predetermined threshold voltage and can no more become a supply voltage. Therefore, the electrostatic discharge circuit 130 of the embodiments of the present disclosure can prevent transistors from being damaged by a surge voltage greater than the magnitude of the predetermined threshold voltage and smaller than the magnitude of the sum of the predetermined threshold voltage and the supply voltage.

In a situation that the electrostatic discharge circuit 130 applies a supply voltage under the receiving mode to the RF transceiver 10 to shut down the RF transceiver 10, if the resistor 138 is not disposed to connect the ESD node 132, a plurality of diodes connected in series have to be provided in order to avoid turning on the diodes in the receiving operations of the RF transceiver 10. In the electrostatic discharge circuit 130 of the embodiments of the present disclosure, there is no need to connect N-numbered diodes in series and thus the turn-on voltage of the diodes may be reduced to 1/N of that voltage.

In a situation that the electrostatic discharge circuit 130 does not apply a supply voltage to the RF transceiver 10, the magnitude of the peak voltage of the ESD node 132 is specified to the magnitude of a specific voltage. If the resistor 138 is not deployed, the magnitude of the peak voltage of the ESD node 132 may become the magnitude of an unknown voltage. That is, system performance may become unstable if the magnitude of the peak voltage of the ESD node 132 is not specified. Therefore, the electrostatic discharge circuit 130 of the embodiments of the present disclosure can prevent transistors from being damaged by a surge voltage greater than the magnitude of the predetermined threshold voltage and smaller than the magnitude of the sum of the predetermined threshold voltage and the unknown voltage.

The device of the embodiments of the present disclosure may be implemented by a device communicating with various apparatuses or wired/wireless communication networks, for example, a device including a part of or all of a modem, a memory storing program instructions, and a micro processor executing the program instructions to calculate and command. The device may be carried out in a logic circuit by hardware, firmware, software, or their combinations, or by a general-purpose or special-purpose computer as well. The device may be implemented by hardwired apparatuses, FPGA (Field Programmable Gate Array), or ASIC (Application Specific Integrated Circuit). Also, the device may be carried out by SoC (System on Chip) including more than one processors or controllers.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A transceiver switch of a radio frequency (RF) transceiver, comprising:
a transmitting circuit comprising a first switch connected between an output port of a power amplifier of the RF transceiver and an input output port of the RF transceiver; and
a receiving circuit comprising a second switch connected between an input port of a low noise amplifier of the RF transceiver and a ground terminal, the input port of the low noise amplifier of the RF transceiver coupled to the input output port of the RF transceiver via inductive coupling,
wherein the receiving circuit further comprises an electrostatic discharge circuit, which releases a surge voltage applied to the input output port of the RF transceiver if a magnitude of the surge voltage is greater than or equal to that of a discharge starting voltage of the electrostatic discharge circuit, and wherein the electrostatic discharge circuit comprising an electrostatic discharge node connecting to the second switch.

2. The transceiver switch according to claim 1, wherein:
the first switch is turned on in response to a transmitting signal in a transmitting state, to connect the output port of the power amplifier of the RF transceiver to the input output port of the RF transceiver; and
the first switch is turned off in response to a receiving signal in a receiving state, to disconnect the output port of the power amplifier of the RF transceiver from the input output port of the RF transceiver.

3. The transceiver switch according to claim 1, wherein:
the second switch is turned on in response to a transmitting signal in a transmitting state, to connect the input port of the low noise amplifier of the RF transceiver to the ground terminal; and
the second switch is turned off in response to a receiving signal in a receiving state, to disconnect the input port of the low noise amplifier of the RF transceiver from the ground terminal.

4. The transceiver switch according to claim 1, wherein the transmitting circuit further comprises a BALUN (BALanced-to-UNbalanced) transformer, which is connected to the output port of the power amplifier of the RF transceiver to convert a differential output signal to a single ended output signal.

5. The transceiver switch according to claim 1, wherein at least one of the first switch and the second switch comprises a transistor.

6. The transceiver switch according to claim 1, wherein the electrostatic discharge circuit is coupled to the input port of the low noise amplifier of the RF transceiver via capacitive coupling.

7. The transceiver switch according to claim 1, wherein the electrostatic discharge circuit comprises a first diode and a second diode, each of which is connected between the electrostatic discharge node and the ground terminal.

8. The transceiver switch according to claim 7, wherein the first diode is connected between the electrostatic discharge node and the ground terminal along a first direction, the second diode is connected between the electrostatic discharge node and the ground terminal along a second direction, and the first direction and the second direction are opposite to each other.

9. The transceiver switch according to claim 1, wherein the magnitude of the discharge starting voltage is an absolute value of a sum of a predetermined threshold voltage and a voltage of the electrostatic discharge node, and the voltage of the electrostatic discharge node is a DC (Direct Current) voltage connected to the ground terminal.

10. The transceiver switch according to claim 1, wherein a magnitude of a peak voltage of the electrostatic discharge node is specified to that of a specific voltage in a situation that the electrostatic discharge circuit does not apply a supply voltage to the RF transceiver.

11. The transceiver switch according to claim 1, wherein the discharge starting voltage changes to a predetermined threshold voltage and changes not to become a supply voltage in a situation that the electrostatic discharge circuit applies the supply voltage to the RF transceiver to shut down the RF transceiver.

12. The transceiver switch according to claim 1, wherein the electrostatic discharge circuit comprises a resistor connected between the electrostatic discharge node and the ground terminal.

13. A radio frequency (RF) transceiver, comprising a transceiver switch, a wireless transmitter, and a wireless receiver, the transceiver switch comprising:
a transmitting circuit comprising a first switch connected between an output port of a power amplifier of the RF transceiver and an input output port of the RF transceiver; and
a receiving circuit comprising a second switch connected between an input port of a low noise amplifier of the RF transceiver and a ground terminal, the input port of the low noise amplifier of the RF transceiver coupled to the input output port of the RF transceiver via inductive coupling,
wherein the receiving circuit further comprises an electrostatic discharge circuit, which releases a surge voltage applied to the input output port of the RF transceiver if a magnitude of the surge voltage is greater than or equal to that of a discharge starting voltage of the electrostatic discharge circuit, and wherein the electrostatic discharge circuit comprising an electrostatic discharge node connecting to the second switch.

14. The RF transceiver according to claim 13, wherein the electrostatic discharge circuit comprises a first diode and a second diode, the first diode is connected between the electrostatic discharge node and the ground terminal along a first direction, the second diode is connected between the electrostatic discharge node and the ground terminal along a second direction, and the first direction and the second direction are opposite to each other.

15. The RF transceiver according to claim 13, wherein the magnitude of the discharge starting voltage is an absolute value of a sum of a predetermined threshold voltage and a voltage of the electrostatic discharge node, and the voltage of the electrostatic discharge node is a DC (Direct Current) voltage connected to the ground terminal.
